(19) United States
(12) Patent Application Publication
(10) Pub. No.: US 2025/0393397 A1
(43) Pub. Date: Dec. 25, 2025

(54) DISPLAY DEVICE

(71) Applicant: Japan Display Inc., Tokyo (JP)

(72) Inventors: Akihiro HANADA, Tokyo (JP); Motochika YUKAWA, Tokyo (JP); Takuo KAITOH, Tokyo (JP)

(73) Assignee: Japan Display Inc., Tokyo (JP)

(21) Appl. No.: 19/236,057

(22) Filed: Jun. 12, 2025

(30) Foreign Application Priority Data
Jun. 20, 2024 (JP) 2024-099518
May 16, 2025 (JP) 2025-082839

(51) Int. Cl. H10K 59/121

(52) U.S. Cl. CPC H10K 59/1213

(57) ABSTRACT

A display device includes a plurality of pixels on an insulating surface, the plurality of pixels including a transistor with an oxide semiconductor layer, a gate wiring facing the oxide semiconductor layer, and a gate insulating layer between the oxide semiconductor layer and the gate wiring, a first insulating layer on the transistor, a first transparent conductive layer on the first insulating layer connected to the oxide semiconductor layer via a first contact hole provided in the first insulating layer and the gate insulating layer, a second insulating layer having a first opening exposing a part of the first transparent conductive layer, a first organic layer having a second opening exposing the part of the first transparent conductive layer on the second insulating layer, and a second transparent conductive layer connected to the first transparent conductive layer on the first organic layer.

### CROSS-REFERENCE TO RELATED APPLICATIONS

This application claims the benefit of priority to Japanese Patent Application No. 2024-099518, filed on Jun. 20, 2024, and Japanese Patent Application No. 2025-082839, filed on May 16, 2025, the entire contents of which are incorporated herein by reference.

### FIELD

An embodiment of the present invention relates to a display device. In particular, an embodiment of the present invention relates to a display device in which a transistor including an oxide semiconductor is used.

### BACKGROUND

Recently, a transistor using an oxide semiconductor for a channel has been developed instead of amorphous silicon, low-temperature polysilicon, and single-crystal silicon (see, for example, Japanese laid-open patent publication No. 2014-146819 and Japanese laid-open patent publication No. 2015-159315). The transistor in which the oxide semiconductor is used for the channel is formed with a simple structure and by low-temperature processing, similar to the transistor in which amorphous silicon is used for the channel. The transistor using the oxide semiconductor for the channel is known to have higher mobility than the transistor using amorphous silicon for the channel and a very low off-state current.

In recent years, the pixel size of a display device has been reduced. With the reduction in the pixel size, the reduction in wiring width and transistor size has been studied. However, this reduction is limited, and the aperture ratio is reduced due to the arrangement of metal layers and semiconductor layers constituting a pixel circuit. Therefore, a transistor has been developed in which an oxide semiconductor layer is used for a channel, which can have enough characteristics for driving the pixel circuit even if the transistor size is small, is used for the transistor of the pixel circuit.

### SUMMARY

A display device according to an embodiment of the present invention includes a plurality of pixels on an insulating surface, the plurality of pixels including a transistor with an oxide semiconductor layer, a gate wiring facing the oxide semiconductor layer, and a gate insulating layer between the oxide semiconductor layer and the gate wiring, a first insulating layer on the transistor, a first transparent conductive layer on the first insulating layer connected to the oxide semiconductor layer via a first contact hole provided in the first insulating layer and the gate insulating layer, a second insulating layer having a first opening exposing a part of the first transparent conductive layer, a first organic layer having a second opening exposing the part of the first transparent conductive layer on the second insulating layer, and a second transparent conductive layer connected to the first transparent conductive layer on the first organic layer, wherein the first contact hole is covered with the first transparent conductive layer, and a part of an edge of the first transparent conductive layer is arranged inside the second opening.

### BRIEF DESCRIPTION OF DRAWINGS

FIG. 1 is a plan view showing an outline of a display device according to an embodiment of the present invention.

FIG. 2 is a block diagram showing a circuit configuration of a display device according to an embodiment of the present invention.

FIG. 3 is a circuit diagram showing a pixel circuit of a pixel of a display device according to an embodiment of the present invention.

FIG. 4 is an end view showing a configuration of a display device according to an embodiment of the present invention.

FIG. 5 is a layout diagram of a plurality of pixels arranged in a display region of a display device according to an embodiment of the present invention.

FIG. 6 is a layout diagram of a plurality of pixels arranged in a display region of a display device according to an embodiment of the present invention.

FIG. 7 is an enlarged view of a part of a pixel among the plurality of pixels shown in FIG. 5.

FIG. 8 is an end view of the pixel shown in FIG. 7 taken along a line A1-A2.

FIG. 9 is a plan view illustrating layouts of respective layers in a display device according to an embodiment of the present invention.

FIG. 10 is a plan view illustrating layouts of respective layers in a display device according to an embodiment of the present invention.

FIG. 11 is a plan view illustrating layouts of respective layers in a display device according to an embodiment of the present invention.

FIG. 12 is a plan view illustrating layouts of respective layers in a display device according to an embodiment of the present invention.

FIG. 13 is a plan view illustrating layouts of respective layers in a display device according to an embodiment of the present invention.

FIG. 14 is a plan view illustrating layouts of respective layers in a display device according to an embodiment of the present invention.

FIG. 15 is a plan view illustrating layouts of respective layers in a display device according to an embodiment of the present invention.

FIG. 16 is a layout diagram of a plurality of pixels arranged in a display region of a display device according to an embodiment of the present invention.

FIG. 17 is an enlarged view of a part of a pixel among the plurality of pixels shown in FIG. 16.

FIG. 18 is an end view of the pixel shown in FIG. 17 taken along a line B1-B2.

FIG. 19 is another end view of the pixel shown in FIG. 17 taken along the line B1-B2.

FIG. 20 is a layout diagram of a plurality of pixels arranged in a display region of a display device according to an embodiment of the present invention.

FIG. 21 is an enlarged view of a part of a pixel among the plurality of pixels shown in FIG. 20.

FIG. 22 is an end view of the pixel shown in FIG. 21 taken along a line C1-C2.

FIG. 23 is a layout diagram of a pixel of a display device of a comparative example.

FIG. 24 is an end view of the pixel shown in FIG. 23 taken along a line E1-E2.

### DESCRIPTION OF EMBODIMENTS

As the resolution of a pixel in a display device is improved, there is a concern that the layout margin of the pixel is narrowed. This may affect the reliability of the display device due to the fluctuation in the characteristics of a transistor using an oxide semiconductor layer or poor connectivity of wiring or the like.

An object of an embodiment of the present invention is to improve the reliability in a display device having high-definition pixels.

Hereinafter, embodiments of the present invention will be described with reference to the drawings. The following invention is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the widths, thicknesses, shapes, and the like of the respective portions in comparison with the actual embodiments. However, the illustrated shapes are merely examples, and do not limit the interpretation of the present invention. In the present specification and the drawings, the same components as those described above with respect to the above-described drawings are denoted by the same reference signs, and a detailed description thereof may be omitted as appropriate.

In the embodiments of the present invention, a direction from a substrate toward an oxide semiconductor layer is referred to as “upper” or “above”. Conversely, a direction from the oxide semiconductor layer toward the substrate is referred to as “lower” or “below”. In this way, for convenience of explanation, the phrases “above” or “below” are used for description, but for example, the substrate and the oxide semiconductor layer may be arranged in a different direction from that shown in the figures. In the following explanation, for example, the expression “oxide semiconductor layer on a substrate” merely describes the upper and lower relation between the substrate and the oxide semiconductor layer as described above, and another member may be arranged between the substrate and the oxide semiconductor layer. The phrases “above” or “below” mean a stacking order in a structure in which a plurality of layers is stacked, and when expressed as a pixel electrode above a transistor, it may be a positional relationship in which the transistor and the pixel electrode do not overlap in a plan view. On the other hand, when expressed as a pixel electrode vertically above a transistor, it means a positional relationship in which the transistor and the pixel electrode overlap in a plan view.

A “display device” refers to a structure that displays an image using an electro-optical layer. For example, the term “display device” may refer to a display panel that includes the electro-optical layer, or may refer to a structure with another optical member (e.g., a polarized member, a backlight, a touch panel, etc.) attached to a display cell. The “electro-optical layer” may include a liquid crystal layer, an electroluminescent (EL) layer, an electrochromic (EC) layer, and an electrophoretic layer, as long as there is no technical contradiction. Therefore, although a liquid crystal display device including a liquid crystal layer is exemplified as the display device in the embodiments described later, the structure in the present embodiment can be applied to a display device including the other electro-optical layers described above.

In the present specification, the expressions “a includes A, B, or C,” “a includes any of A, B, and C,” “a includes one selected from a group consisting of A, B, and C,” and the like does not exclude the case where a includes a plurality of combinations of A to C unless otherwise specified. Furthermore, these expressions do not exclude the case where a includes other elements.

In addition, the following embodiments can be combined with each other as long as there is no technical contradiction.

### First Embodiment 1

### [1. Outline of Display Device 10]

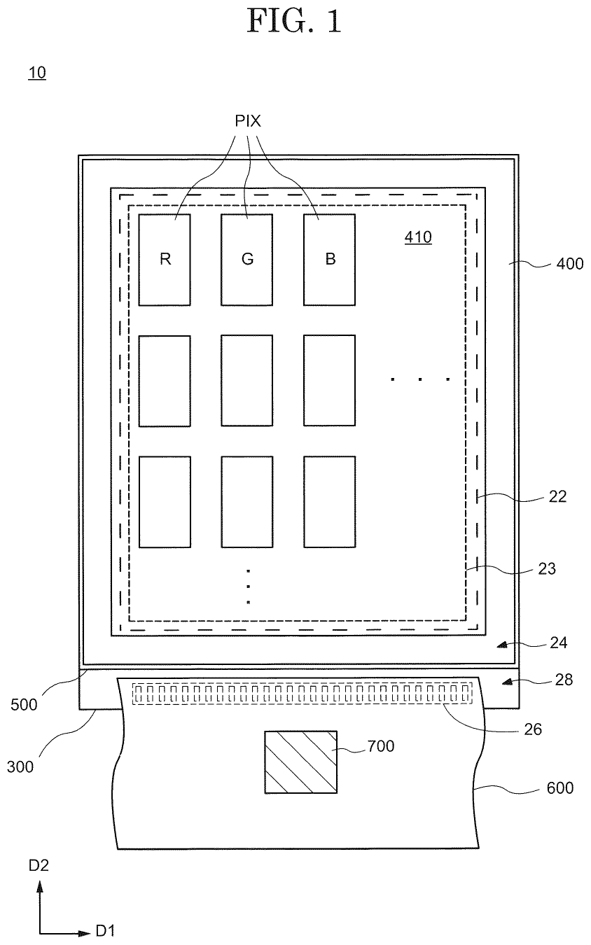

An outline of a display device 10 according to an embodiment of the present invention will be described with reference to FIG. 1 to FIG. 3. FIG. 1 is a plan view schematically showing the display device 10 according to an embodiment of the present invention. As shown in FIG. 1, the display device 10 includes an array substrate 300, a seal material 400, a counter substrate 500, and a flexible printed circuit board 600 (FPC 600), and an IC chip 700. The array substrate 300 and the counter substrate 500 are bonded together with the seal material 400. In a liquid crystal region 22 surrounded by the seal material 400, a plurality of pixels PIX is arranged in a matrix along a first direction D1 (row direction) and a second direction D2 (column direction) intersecting the first direction D1. The plurality of pixels PIX includes a red pixel R, a green pixel G, and a blue pixel B according to a color filter provided in the counter substrate. The first direction D1 and the second direction D2 may be perpendicular to each other. Although not shown in FIG. 1, a direction perpendicular to the surface of the array substrate 300 will be described as a direction D3. The liquid crystal region 22 is a region that overlaps a liquid crystal element LE to be described later in a plan view. Hereinafter, a region including a plurality of pixels of the liquid crystal region 22 may be referred to as a display region 23.

In addition, the display device 10 has a backlight unit on the back of the array substrate 300, and when light emitted from the backlight unit transmits through the display region 23, the transmitted light is modulated in each pixel PIX, so that an image is displayed.

A sealing region 24 where the seal material 400 is provided is a region around the liquid crystal region 22. The FPC 600 is attached to a terminal region 26. The terminal region 26 is provided in a region where the array substrate 300 does not overlap the counter substrate 500 and is provided outside of the sealing region 24. In addition, the outside of the sealing region 24 means the outside of the region where the seal material 400 is provided and the region surrounded by the seal material 400. The IC chip 700 is provided on the FPC 600. The IC chip 700 supplies a signal for driving a pixel circuit of each pixel PIX. Hereinafter, the sealing region 24, outside of the sealing region 24, and the terminal region 26 are collectively referred to as a frame region 28. The IC chip 700 may be mounted on the frame region 28.

### [2. Circuit Configuration of Display Device 10]

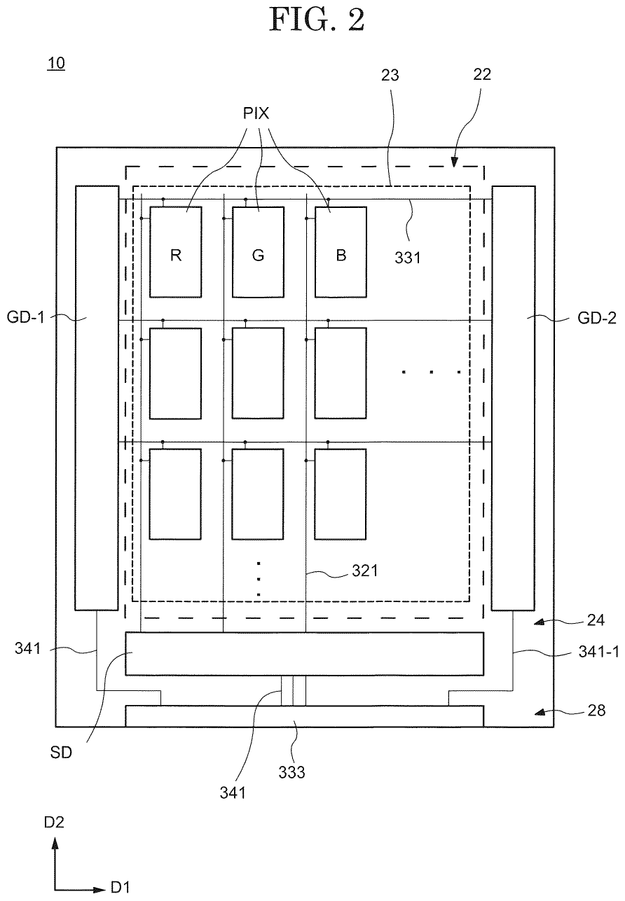

FIG. 2 is a diagram showing a configuration of the display device 10 according to an embodiment of the present invention. As shown in FIG. 2, with respect to the liquid crystal region 22 in which the pixel PIX is arranged, a source driver circuit SD is provided along the first direction D1, and with respect to the liquid crystal region 22, gate driver circuits GD-1 and GD-2 are provided along the second direction D2. The source driver circuit SD and the gate driver circuits GD-1 and GD-2 are provided in the sealing region 24. However, the region in which the source driver circuit SD and the gate driver circuits GD-1 and GD-2 are provided is not limited to the sealing region 24, and may be any region outside the region in which the pixel circuit of the pixel PIX is provided. Further, a configuration in which the source driver circuit is provided within the IC chip 700 may also be employed.

A source wiring 321 extends from the source driver circuit SD in the second direction D2 and is connected to the pixel circuits of the plurality of pixels PIX arranged in the second direction D2. A gate wiring 331 extends from the gate driver circuit GD-1 or the gate driver circuit GD-2 in the first direction D1 and is connected to the pixel circuits of the plurality of pixels PIX arranged in the first direction D1.

A terminal part 333 is provided in the terminal region 26. The terminal part 333 and the source driver circuit SD are connected by a connecting wiring 341. Similarly, the terminal part 333 and the gate driver circuits GD-1 and GD-2 are connected by the connecting wiring 341. When the FPC 600 is connected to the terminal part 333, an external device to which the FPC 600 is connected is connected to the display device 10, and the pixel circuits included in the respective pixels PIX provided in the display device 10 are driven by a signal from the external device.

### [3. Pixel Circuit of Pixel PIX of Display Device 10]

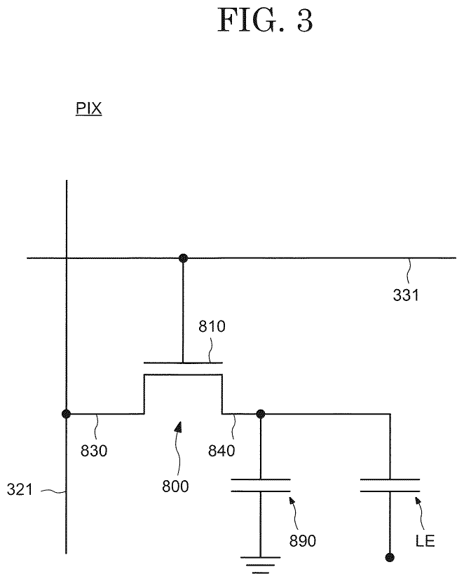

FIG. 3 is a circuit diagram showing the pixel circuit of the pixel PIX of the display device 10 according to an embodiment of the present invention. As shown in FIG. 3, the pixel circuit includes elements such as a transistor 800, a storage capacitor 890, and a liquid crystal element LE. Although details will be described later, one electrode of the liquid crystal element LE is a pixel electrode, and the other electrode is a common electrode. In addition, one electrode of the storage capacitor 890 serves as a pixel electrode, and the other electrode serves as a common electrode.

The transistor 800 includes a first gate electrode 810, a first source electrode 830, and a first drain electrode 840. The first gate electrode 810 is connected to the gate wiring 331. The first source electrode 830 is connected to the source wiring 321. The first drain electrode 840 is connected to the storage capacitor 890 and the liquid crystal element LE. Further, in the present embodiment, for convenience of explanation, 830B is referred to as a source electrode, and 840B is referred to as a drain electrode, but the source and drain functions of each of the electrodes may be interchanged.

### [4. Configuration of Display Device 10]

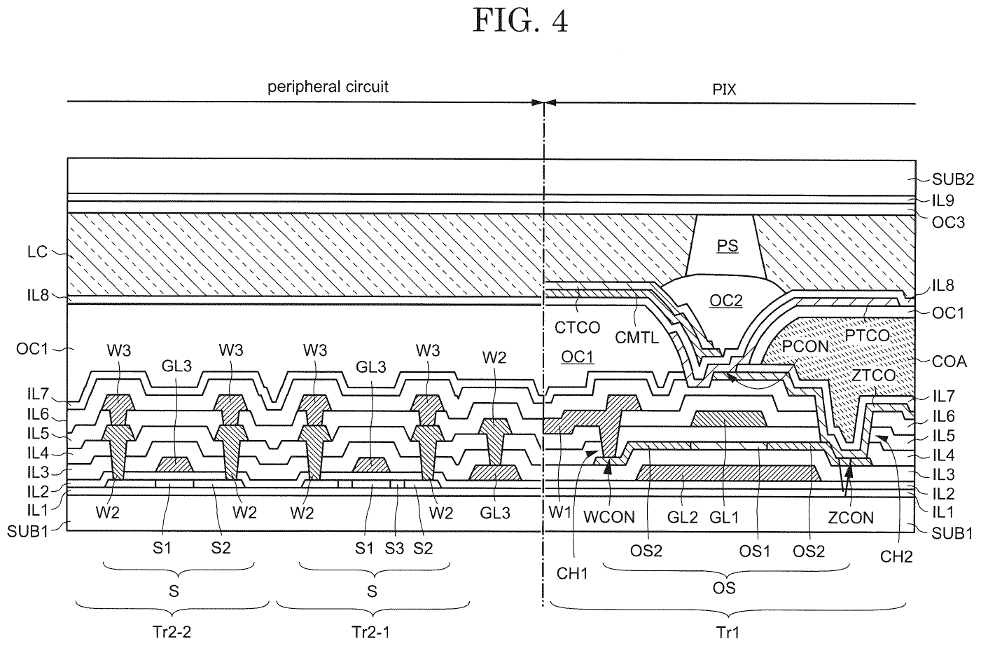

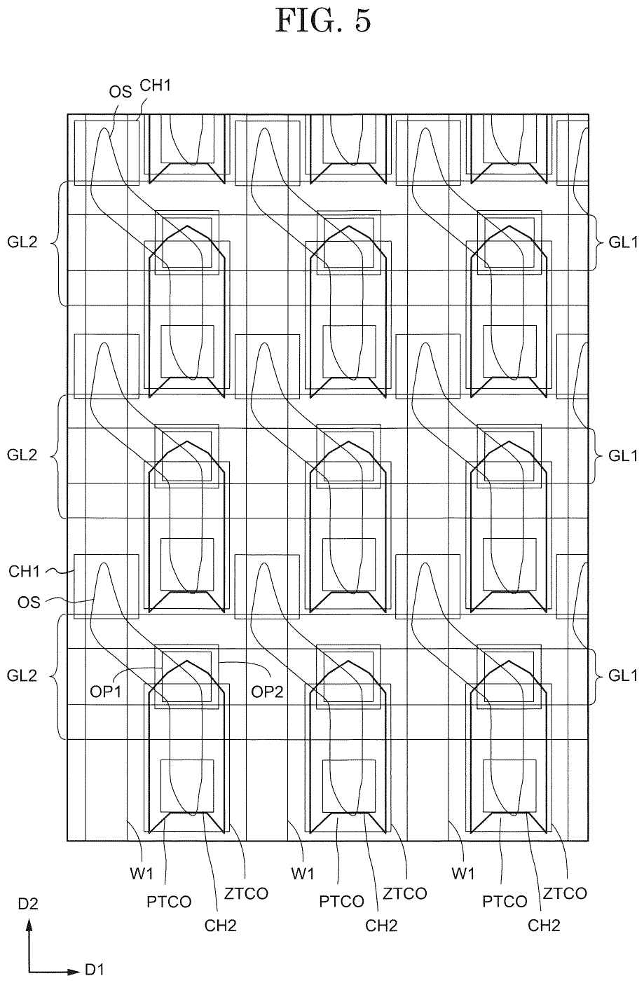

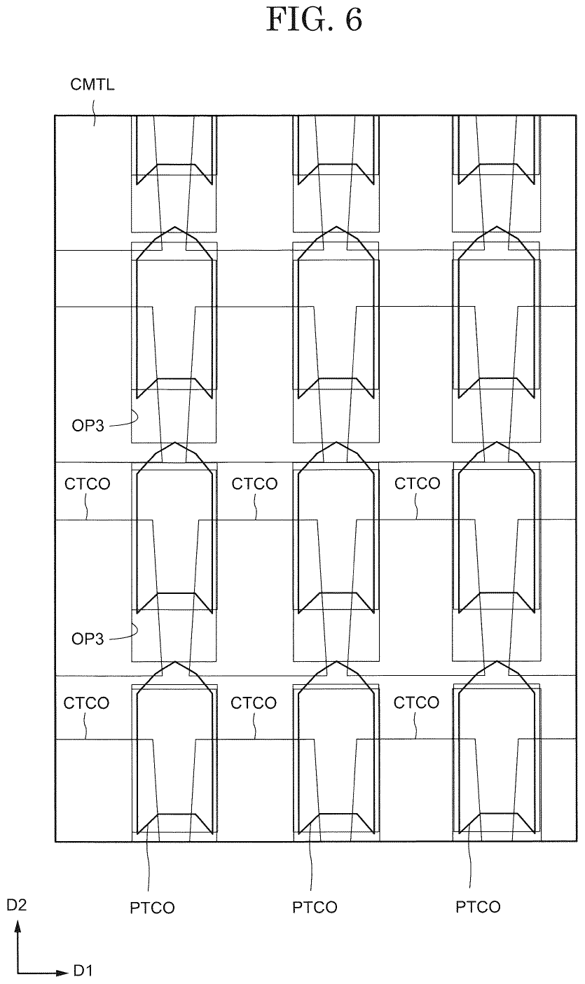

A detailed configuration of the display device 10 according to an embodiment of the present invention will be described with reference to FIG. 4 and FIG. 5. FIG. 4 is an end view showing the configuration of the display device 10 according to an embodiment of the present invention. FIG. 5 and FIG. 6 are layout diagrams of the plurality of pixels arranged in the display region 23 of the display device 10 according to an embodiment of the present invention. In addition, the end view shown in FIG. 4 is an end view for explaining a layer structure of the display device 10, in which a peripheral circuit and the pixel PIX are shown adjacent to each other. In practice, the pixel PIX is provided in the display region 23, and the peripheral circuit is provided in the frame region 28 outside the display region 23, so it goes without saying that the peripheral circuit and the pixel

PIX are spaced apart from each other. Further, in particular, in the pixel PIX shown in FIG. 4, a transistor Tr1 in the pixel PIX is mainly shown, and only a part of an opening region (translucent region) that contributes to displaying is shown.

### [5. Configuration of Pixel Circuit]

The display device 10 includes the plurality of pixels PIX provided on an insulating surface. As shown in FIG. 4, each of the plurality of pixels PIX includes at least the transistor Tr1, a first insulating layer including a fifth insulating layer IL5 and a sixth insulating layer IL6, a connection electrode ZTCO, a seventh insulating layer IL7, an organic layer including a color filter COA and an overcoat OC1, and a pixel electrode PTCO. In addition, TCO is an abbreviation for Transparent Conductive Oxide.

The transistor Tr1 is a transistor included in the pixel circuit of the pixel PIX of the display device 10. The transistor Tr1 (the transistor 800 shown in FIG. 3) is provided on a third insulating layer IL3. The transistor Tr1 has an oxide semiconductor layer OS, a fourth insulating layer IL4, and a gate wiring GL1 (the first gate electrode 810 shown in FIG. 3). The gate wiring GL1 faces the oxide semiconductor layer OS. In addition, part of the gate wiring GL1 functions as the gate electrode. The fourth insulating layer IL4 is provided between the oxide semiconductor layer OS and the gate wiring GL1. The fourth insulating layer IL4 functions as a gate insulating layer. In the present embodiment, although a top-gate transistor in which the oxide semiconductor layer OS is provided on a side closer to an array substrate SUB1 than the gate wiring GL1 is exemplified, a bottom-gate transistor in which the positional relationship between the gate wiring GL1 and the oxide semiconductor layer OS is reversed may be used.

The oxide semiconductor layer OS includes oxide semiconductor regions OS1 and OS2. The oxide semiconductor region OS1 is an oxide semiconductor layer in a region that overlaps the gate wiring GL1 in a plan view. The oxide semiconductor region OS1 functions as a semiconductor and is switched between a conductive state and a non-conductive state depending on a voltage supplied to the gate wiring GL1. That is, the oxide semiconductor region OS1 functions as a channel of the transistor Tr1. An impurity element is added to the oxide semiconductor region OS2 and functions as a conductor.

The fifth insulating layer IL5 is provided on the gate wiring GL1. A wiring W1 (the source wiring 321 shown in FIG. 3) is provided on the fifth insulating layer IL5. The wiring W1 is connected to the oxide semiconductor region OS2 via a contact hole CH1 provided in the fifth insulating layer IL5 and the fourth insulating layer IL4. A data signal related to the gradation of the pixel is transmitted to the wiring W1. The sixth insulating layer IL6 is provided on the fifth insulating layer IL5 and the wiring W1. The fifth insulating layer IL5 and the sixth insulating layer IL6 may be referred to as the first insulating layer. In addition, the fifth insulating layer IL5 and the sixth insulating layer IL6 are formed using an inorganic insulating material.

The connection electrode ZTCO (the first drain electrode 840 shown in FIG. 3) is provided on the sixth insulating layer IL6. The connection electrode ZTCO is connected to the oxide semiconductor region OS2 via a contact hole CH2 provided in the fourth insulating layer IL4, the fifth insulating layer IL5, and the sixth insulating layer IL6. The connection electrode ZTCO is in contact with the oxide semiconductor region OS2 at the bottom of the contact hole CH2. The connection electrode ZTCO is formed using a transparent conductive material.

A region where the connection electrode ZTCO and the oxide semiconductor region OS2 contact each other is called a contact region ZCON. The connection electrode ZTCO contacts the oxide semiconductor region OS2 in the contact region ZCON not overlapping the gate wiring GL1 and the wiring W1 in a plan view. In a plan view, the contact region ZCON is included in an opening region of the pixel. As shown in FIG. 5, the opening region of the pixel is a region surrounded by a gate wiring GL2 extending in the first direction D1 and the wiring W1.

For example, when a transparent conductive layer such as an ITO layer or the like is formed so as to be in contact with a semiconductor layer such as a silicon layer, the surface of the semiconductor layer is oxidized by a process gas and oxygen ions at the time of deposition. Since the oxide layer formed on the semiconductor layer has a high resistance, the contact resistance between the semiconductor layer and the transparent conductive layer increases. As a result, poor electrical contact occurs between the semiconductor layer and a transparent conductive layer. On the other hand, even if the transparent conductive layer is formed in contact with the oxide semiconductor layer, the high resistance oxide layer as described above is hardly formed on the oxide semiconductor layer. Therefore, poor electrical contact between the oxide semiconductor layer and the transparent conductive layer is unlikely to occur.

The seventh insulating layer IL7 is provided on the connection electrode ZTCO. As shown in FIG. 5, an opening OP1 is provided in the seventh insulating layer IL7, and a part of the connection electrode ZTCO and the sixth insulating layer IL6 is exposed. For example, the seventh insulating layer IL7 is formed using an inorganic insulating material having a function of blocking moisture. As a result, even if an organic layer described later is formed on the transistor Tr1, it is possible to suppress the moisture contained in the organic layer from entering the oxide semiconductor layer OS of the transistor Tr1.

The color filter COA and the overcoat OC1 are provided on the seventh insulating layer IL7. Since the color filters COA and the overcoat OC1 are formed using an organic material, they may be referred to as an organic layer. For example, red, green, and blue color filters are used as the color filter COA. The higher the definition in the display device 10, the more difficult it is to align the color filters provided on a counter substrate SUB2 side and the pixel circuit provided on the array substrate SUB1 side. In addition, the color filter COA may not be provided on the wiring W1. A region in which the color filter COA is arranged is a region that transmits the light from the backlight at the opening region of the pixel. The light from the backlight is transmitted from the array substrate SUB1 through the region where the connection electrode ZTCO and the color filter COA are arranged, and is emitted from the counter substrate SUB2. The overcoat OC1 releases a step formed by a structure provided below the overcoat OC1. Therefore, the overcoat OC1 may be referred to as a planarization film. As shown in FIG. 5, an opening OP2 is provided in the overcoat OC1, and a part of the seventh insulating layer IL7 and the connection electrode ZTCO is exposed.

The pixel electrode PTCO is provided on the overcoat OC1 via the opening OP2. The pixel electrode PTCO is connected to the connection electrode ZTCO via the openings OP1 and OP2. A region where the connection electrode ZTCO and the pixel electrode PTCO contact each other is called a contact region PCON. In a plan view, the contact region PCON overlaps the gate wiring GL1. The pixel electrode PTCO is formed using a transparent conductive material. An eighth insulating layer IL8 is provided on the pixel electrode PTCO and the overcoat OC1.

As shown in FIG. 4 and FIG. 6, a common auxiliary electrode CMTL and a common electrode CTCO are provided on the eighth insulating layer IL8. The common electrode CTCO is provided in contact with the common auxiliary electrode CMTL. The pixel electrode PTCO, the eighth insulating layer IL8, and the common electrode CTCO constitute the storage capacitor 890. The common auxiliary electrode CMTL and the common electrode CTCO have different planar patterns. In this case, a part of the connection electrode ZTCO provided inside the opening OP2 overlaps the common auxiliary electrode CMTL. The common auxiliary electrode CMTL is a metal layer. The common electrode CTCO is a transparent conductive layer. The electrical resistance of the common auxiliary electrode CMTL is lower than the electrical resistance of the common electrode CTCO. In addition, the common auxiliary electrode CMTL also functions as a light-shielding layer. For example, the common auxiliary electrode CMTL blocks light from adjacent pixels, so that the occurrence of color mixing can be suppressed. In the present embodiment, although a configuration is shown in which the common electrode CTCO is provided on the common auxiliary electrode CMTL, a configuration in which the common auxiliary electrode CMTL is provided on the common electrode CTCO may be employed.

An overcoat OC2 is provided on the eighth insulating layer IL8 and the common electrode CTCO so as to fill the inside of the opening OP2 provided in the overcoat OC1. In addition, a spacer PS is provided on and in contact with the overcoat OC2. A part of the end portion of the connection electrode ZTCO provided inside the opening OP2 overlaps the spacer PS. The spacer PS may be provided for some of the pixels. For example, the spacer PS may be provided for any one of the pixels PIX of the red pixel, the green pixel, and the blue pixel. Alternatively, the spacer PS may be provided for all the pixels PIX.

The counter substrate SUB2 is provided with a ninth insulating layer IL9 and an overcoat OC3 on the ninth insulating layer IL9. The array substrate SUB1 and the counter substrate SUB2 are bonded to each other by the seal material 400 (see FIG. 1) so that the overcoat OC3 faces the eighth insulating layer IL8 and the common electrode CTCO. In addition, the cell gap between the array substrate SUB1 and the counter substrate SUB2 is determined by the spacer PS. Further, a liquid crystal layer LC is provided between the array substrate SUB1 and the counter substrate SUB2.

In addition, the gate wiring GL2 may be provided between the transistor Tr1 and the array substrate SUB1. The gate wiring GL2 can control the threshold of the transistor Tr1. In addition, the gate wiring GL2 also functions as a light-shielding film. In a plan view, the gate wiring GL2 is provided in a region where the gate wiring GL1 and the oxide semiconductor layer OS overlap. In other words, in a plan view, the gate wiring GL2 is provided in a region overlapping the oxide semiconductor region OS1. The gate wiring GL2 suppresses the light entering from the array substrate SUB1 side from reaching the oxide semiconductor region OS1. In addition, instead of the gate wiring GL2, a floating conductive layer that shields the oxide semiconductor region OS1 from light may be provided. In a plan view, the contact region ZCON is provided in a region not overlapping the gate wiring GL2.

### [6. Configuration of Peripheral Circuit]

Transistors Tr2-1 and Tr2-2 are transistors included in the peripheral circuit such as the source driver circuit SD or the gate driver circuits GD-1 and GD-2. The transistor Tr2-1 is an n-type transistor, and the transistor Tr2-2 is a p-type transistor.

The n-type transistor Tr2-1 and the p-type transistor Tr2-2 are provided on the first insulating layer IL1. Both the n-type transistor Tr2-1 and the p-type transistor Tr2-2 have a gate wiring GL3 (also referred to as a gate electrode), a second insulating layer IL2, and a semiconductor layer S. The gate wiring GL3 faces the semiconductor layer S. The second insulating layer IL2 is provided between the semiconductor layer S and the gate wiring GL3. In addition, the gate wiring GL3 is formed from the same conductive film as the gate wiring GL2. In the present embodiment, although a top-gate transistor is exemplified in which the gate wiring GL3 is provided on a side closer to the array substrate SUB1 than the semiconductor layer S, a bottom-gate transistor in which the positional relationship between the semiconductor layer S and the gate wiring GL3 is reversed may be used.

The semiconductor layer S of the n-type transistor Tr2-1 includes semiconductor regions S1, S2, and S3. The semiconductor layer S of the p-type transistor Tr2-2 includes the semiconductor regions S1 and S2. The semiconductor region S1 is a semiconductor region of a region overlapping the gate wiring GL3 in a plan view. The semiconductor region S1 functions as a channel of the transistor Tr2-1. The semiconductor region S2 functions as a conductor. The semiconductor region S3 functions as a conductor with a higher resistance than the semiconductor region S2. The semiconductor region S3 suppresses hot carrier degradation by attenuating hot carriers entering the semiconductor region S1.

The third insulating layer IL3 and the fourth insulating layer IL4 are provided on the gate wiring GL3. In the transistors Tr2-1 and Tr2-2, the third insulating layer IL3 and the fourth insulating layer IL4 simply function as interlayer films. A wiring W2 is provided on the fourth insulating layer IL4. The wiring W2 is connected to the semiconductor layer S via the contact hole provided in the second insulating layer IL2, the third insulating layer IL3, and the fourth insulating layer IL4. The wiring W2 is formed from the same conductive film as the gate wiring GL1. The fifth insulating layer IL5 is provided on the wiring W2. A wiring W3 is provided on the fifth insulating layer IL5. The wiring W3 is formed from the same conductive film as the wiring W1. In addition, the wiring W3 is connected to the wiring W2 via the contact hole provided in the fifth insulating layer IL5. The sixth insulating layer IL6 and the seventh insulating layer IL7 are provided on the fifth insulating layer IL5 and the wiring W3. Further, in FIG. 4, since the color filter COA and the pixel electrode PTCO are not provided in the peripheral circuit, illustration thereof is omitted. In addition, the common auxiliary electrode CMTL and the common electrode CTCO may be provided in the peripheral circuit.

### [7. Effect of High Definition of Display Device]

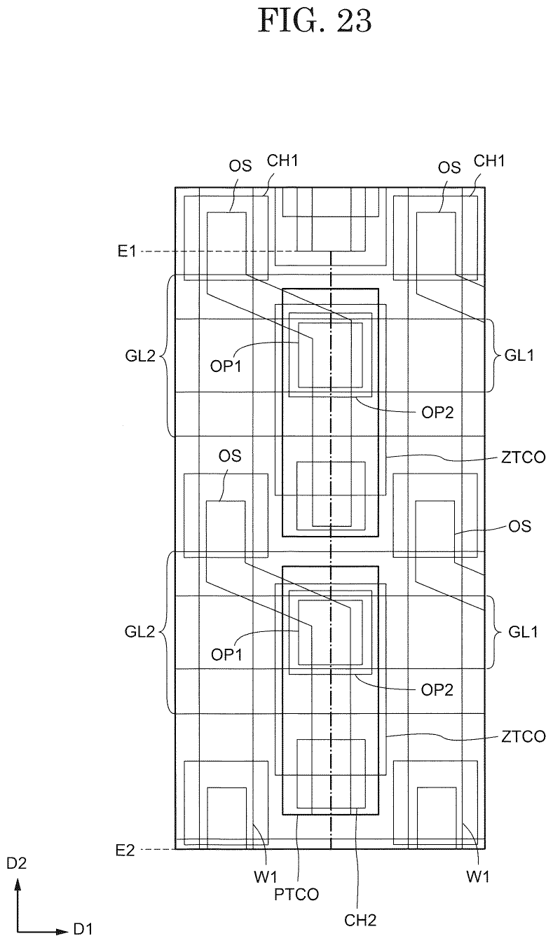

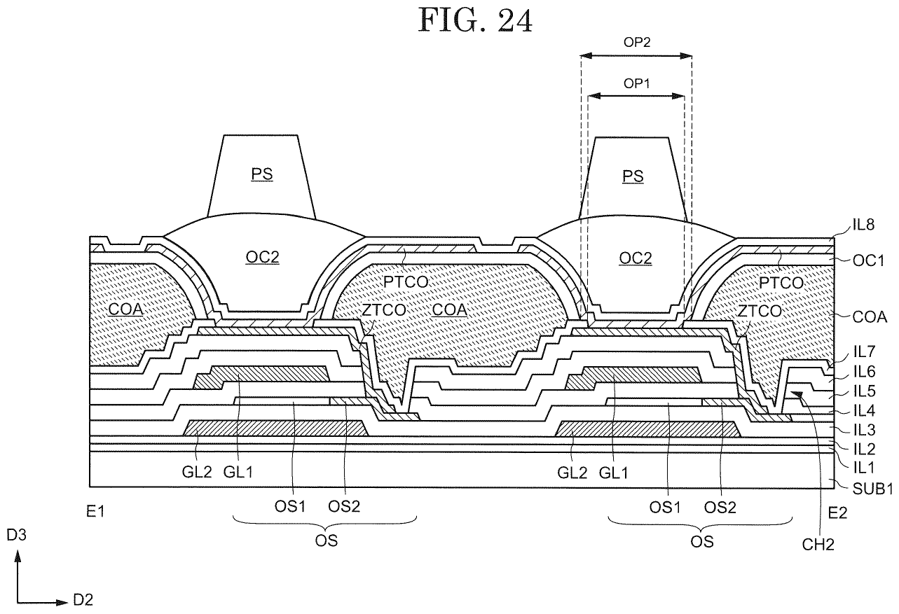

An effect of increasing the definition of a display device will be described with reference to FIG. 23 and FIG. 24. As a display device becomes higher in definition, restrictions on the conductive layers and contact holes for forming the plurality of adjacent pixels become greater. For example, if the conductive layers of the adjacent pixels are too close to each other, there is a risk of short-circuiting. The area of the conductive layer may be reduced in order to suppress short-circuiting between the adjacent conductive layers.

FIG. 23 is a layout diagram of a pixel of a display device according to a comparative example. FIG. 24 is an end view of the pixel shown in FIG. 23 taken along a line E1-E2. Further, in FIG. 23 and FIG. 24, illustration of the common electrode, overcoat, spacer, liquid crystal layer, and counter substrate is omitted. As shown in FIG. 23 and FIG. 24, the connection electrode ZTCO overlaps the gate wiring GL1 on the sixth insulating layer IL6 and is connected to the oxide semiconductor layer OS via the contact hole CH2 provided in the fourth insulating layer IL4 to the sixth insulating layer IL6. In this case, in order to suppress the connection electrodes ZTCO of two adjacent pixels in the second direction D2 from coming close to each other and short-circuiting, the end portion of the connection electrode ZTCO is provided on and in contact with the oxide semiconductor layer OS. When forming the connection electrode ZTCO, the exposed region of the oxide semiconductor layer OS is exposed by an etching solution or etching gas. Since the oxide semiconductor layer OS is also formed of a metal oxide, due to the etching of the connection electrode ZTCO, the oxide semiconductor layer OS also tends to be etched. If the oxide semiconductor layer OS is etched, the coverage of the connection electrode ZTCO and the oxide semiconductor layer OS is deteriorated when the seventh insulating layer IL7 is formed on the connection electrode ZTCO. As a result, the moisture derived from the organic layer may enter the oxide semiconductor layer OS from the region where the coverage of the seventh insulating layer IL7 is deteriorated, and the characteristics of the transistor Tr1 may fluctuate.

In addition, as the display device becomes higher in definition, it is greatly affected by the mask misalignment for forming the oxide semiconductor layers, various conductive layers, and the contact holes. For example, when the oxide semiconductor layer OS and the connection electrode ZTCO are formed via the contact hole CH2 provided in the fourth insulating layer IL4 to the sixth insulating layer IL6, it is greatly affected by the line width of the oxide semiconductor layer OS and the line width of the connection electrode ZTCO, and the misalignment of the respective masks. If the arrangement of the mask of the connection electrode ZTCO and the mask of the contact hole CH2 are misaligned, poor connection may occur between the oxide semiconductor layer OS and the connection electrode ZTCO. Further, as described above, if the oxide semiconductor layer OS is etched when the connection electrode ZTCO is processed and the oxide semiconductor layer OS is exposed, the connection electrode ZTCO and the oxide semiconductor layer OS are more likely to be disconnected.

As described above, as the resolution of the pixel in the display device is improved, there is a concern that the layout margin of the pixel is narrowed. This may affect the reliability of the display device due to the fluctuation in the characteristics of the transistor using the oxide semiconductor layer or the poor connection of wiring, or the like.

An object of an embodiment of the present invention is to improve the reliability in the display device 10 having high-definition pixels.

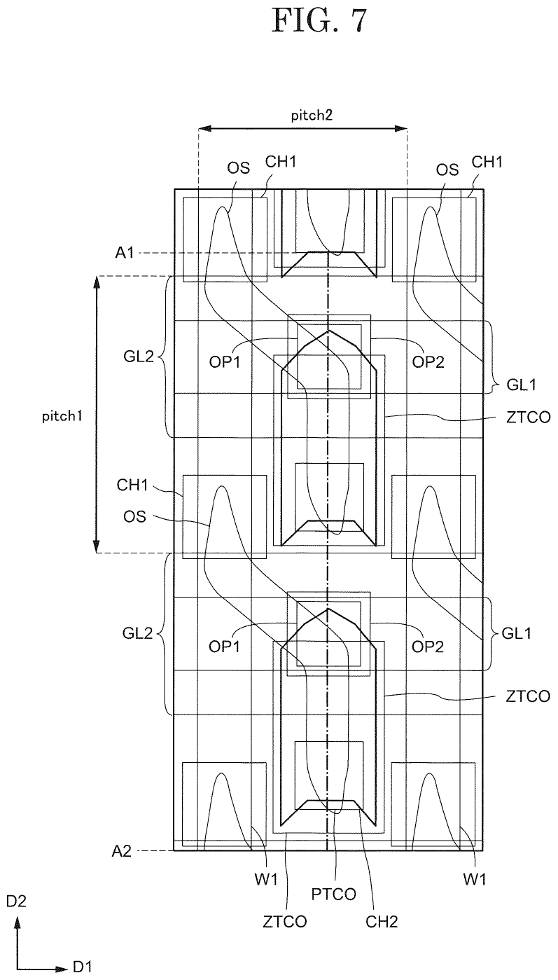

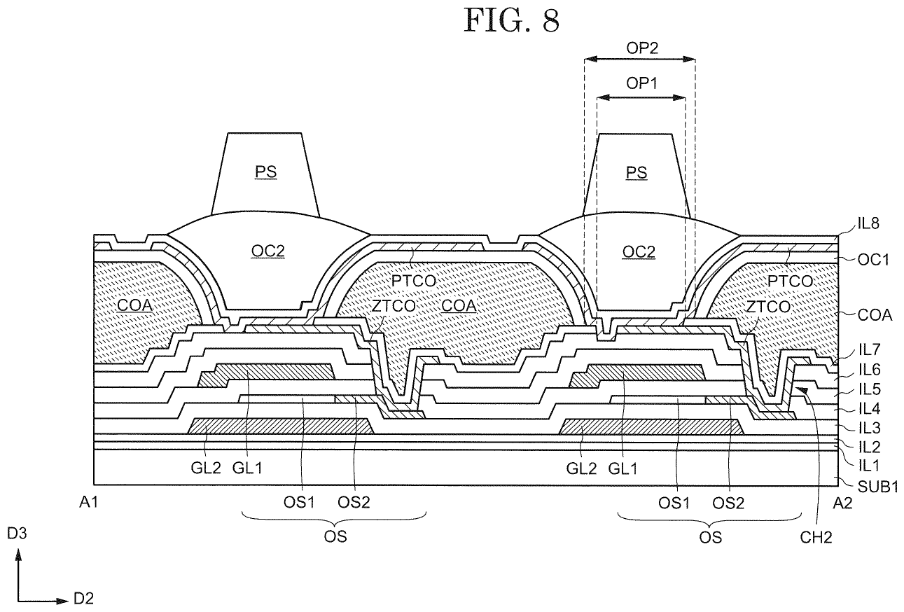

FIG. 7 is an enlarged view of a part of a pixel among the plurality of pixels shown in FIG. 5. FIG. 8 is an end view of the pixel shown in FIG. 7 taken along a line A1-A2. As shown in FIG. 5, in a plan view, an interval pitch1 between the gate wirings GL2 of the two pixels adjacent in the second direction D2 and an interval pitch2 between the wirings W1 of the two pixels adjacent in the first direction D1 are, for example, 4 μm or more and 8 μm or less. The interval pitch1 and the interval pitch2 may be the same or different.

In an embodiment of the present invention, the contact hole CH2 connecting the oxide semiconductor layer OS and the connection electrode ZTCO is covered with the connection electrode ZTCO. As a result, it is possible to prevent the oxide semiconductor layer OS from being exposed when forming the connection electrode ZTCO. In addition, when the connection electrode ZTCO is formed, it is possible to suppress the oxide semiconductor layer OS from being etched. Therefore, when the seventh insulating layer IL7 is formed, the coverage of the connection electrode ZTCO can be improved. As a result, it is possible to suppress the moisture derived from the organic layer from entering the oxide semiconductor layer OS. When the contact hole CH2 is covered with the connection electrode ZTCO, it is possible to suppress a connection failure between the oxide semiconductor layer OS and the connection electrode ZTCO even if a mask misalignment occurs.

A part of the end portion of the connection electrode ZTCO is arranged inside the opening OP2 provided in the seventh insulating layer IL7. In addition, a part of the end portion of the connection electrode ZTCO is arranged inside the opening OP1 provided in the seventh insulating layer IL7. Further, the pixel electrode PTCO covers a part of the end portion of the opening OP1 and is in contact with the connection electrode ZTCO. As a result, since the organic layer can be sealed by the pixel electrode PTCO and the seventh insulating layer IL7, it is possible to suppress moisture derived from the organic layer from entering the transistor Tr1.

In the case where the connection electrode ZTCO covers the entire contact hole CH2, if the connection electrode ZTCO is arranged in the entire opening OP1, the two connection electrodes ZTCO may be short-circuited when the connection electrodes ZTCO are adjacent to each other in the two adjacent pixels in the second direction D2. Therefore, in the case where the connection electrodes ZTCO are adjacent to each other in the two adjacent pixels in the second direction D2, a part of the end portion of the connection electrode ZTCO provided inside the opening OP2 is preferably provided at a position overlapping the gate wiring GL1. A part of the facing end portions of the connection electrode ZTCO may not overlap the gate wiring GL2 of the pixel adjacent in the second direction D2. As a result, even if the length of the connection electrode ZTCO in the second direction D2 is shortened, the connection between the connection electrode ZTCO and the oxide semiconductor layer OS and the connection between the connection electrode ZTCO and the pixel electrode PTCO can be secured. Furthermore, in the case where the connection electrodes ZTCO are adjacent to each other in the two adjacent pixels in the second direction D2, it is possible to suppress the two connection electrodes ZTCO from being short-circuited even if the interval between the two connection electrodes ZTCO is several micrometers. As a result, in the second direction D2, the connection electrodes ZTCO adjacent to each other can be brought close to the processing limit, and the area that contributes to the display in one pixel can be further increased. Similarly, in the second direction D2, since the pixel electrodes adjacent to each other can be brought close to the processing limit, the area that contributes to displaying in one pixel can be further increased.

In the two adjacent pixels in the second direction D2, at least one of the interval between the connection electrode of one pixel and the connection electrode of the other pixel, the interval between the pixel electrode of one pixel and the pixel electrode of the other pixel, and the contact holes CH1 and CH2 may be 2 μm or less. For example, in two adjacent pixels, the interval between the connection electrode of one pixel and the connection electrode of the other pixel may be the same as the length of the contact hole provided in one pixel in the first direction D1. In the two adjacent pixels, the interval between the connection electrode of one pixel and the connection electrode of the other pixel, the interval between the pixel electrode of one pixel and the pixel electrode of the other pixel, and the contact holes CH1 and CH2 may all have the same length. In this case, the same length does not mean that the lengths perfectly match, but that they may be substantially the same length.

According to the display device 10 according to an embodiment of the present invention, it is possible to suppress the fluctuation in the characteristics of the transistor using the oxide semiconductor layer even when the layout margins of the pixel are narrowed as the resolution of the pixel is improved. In addition, a connection failure between the oxide semiconductor layer OS and the connection electrode ZTCO can be suppressed. Therefore, the reliability can be improved in the display device 10 having high-definition pixels.

### [8. Planar Layout of Display Device 10]

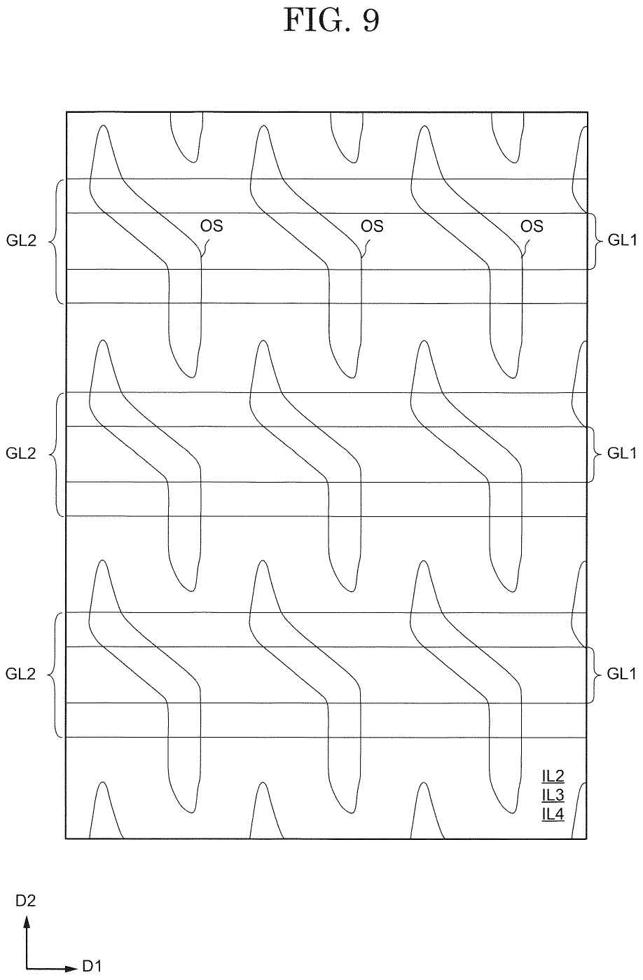

Next, the layout of each layer in the pixel circuit of the display device 10 according to an embodiment of the present invention will be described with reference to FIG. 9 to FIG. 16. In addition, the layout of each layer in the pixel circuit will be described with reference to the end view shown in FIG. 4 as appropriate.

As shown in FIG. 4 and FIG. 9, the gate wiring GL2 is provided on the second insulating layer IL2, extends in the first direction D1, and is commonly provided for the pixels arranged in the first direction D1. The oxide semiconductor layer OS is provided on the third insulating layer IL3 and extends in the second direction D2. The oxide semiconductor layer OS has a curved region. The gate wiring GL1 is provided on the fourth insulating layer IL4 and extends in the first direction D1 to intersect the oxide semiconductor layer OS. The pattern of the gate wiring GL1 is provided inside the pattern of the gate wiring GL2.

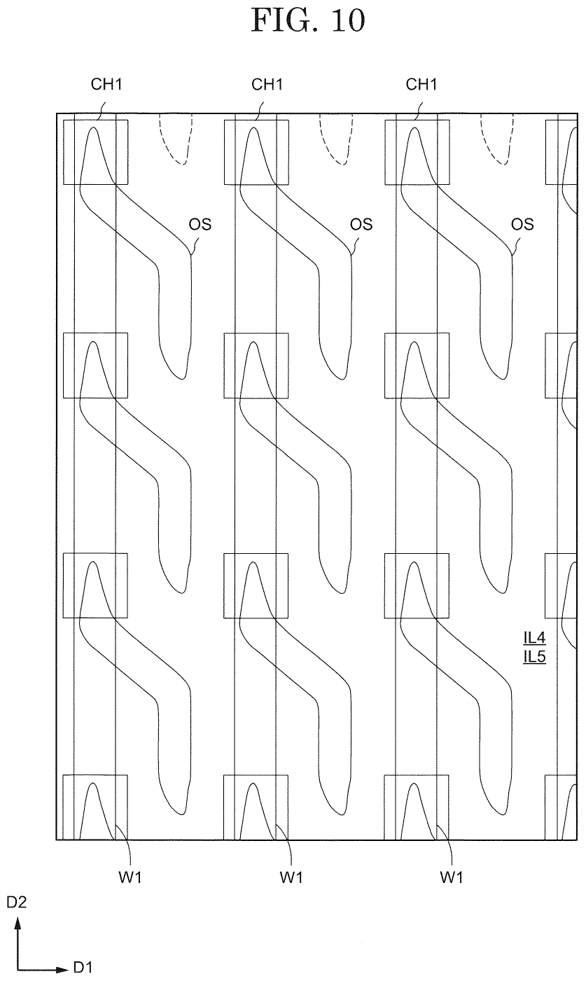

As shown in FIG. 4 and FIG. 10, the contact hole CH1 is provided in a region overlapping the wiring W1 near the upper end of the pattern of the oxide semiconductor layer OS. The contact hole CH1 is formed in the fourth insulating layer IL4 and the fifth insulating layer IL5. The wiring W1 is formed on the fifth insulating layer IL5. The main part of the pattern of the oxide semiconductor layer OS extends in the second direction D2 between the adjacent wirings W1. The wiring W1 is connected to the oxide semiconductor layer OS via the contact hole CH1. The remaining part of the pattern of the oxide semiconductor layer OS extends from the main part toward the region of the contact hole CH1 in a direction oblique to the first direction D1 and the second direction D2, and is bent toward the second direction D2. The plurality of wirings W1 extends in the second direction D2. In this case, the main part of the oxide semiconductor layer OS can be said to extend in the second direction D2 between the two adjacent wirings W1 and intersect the gate wiring GL1.

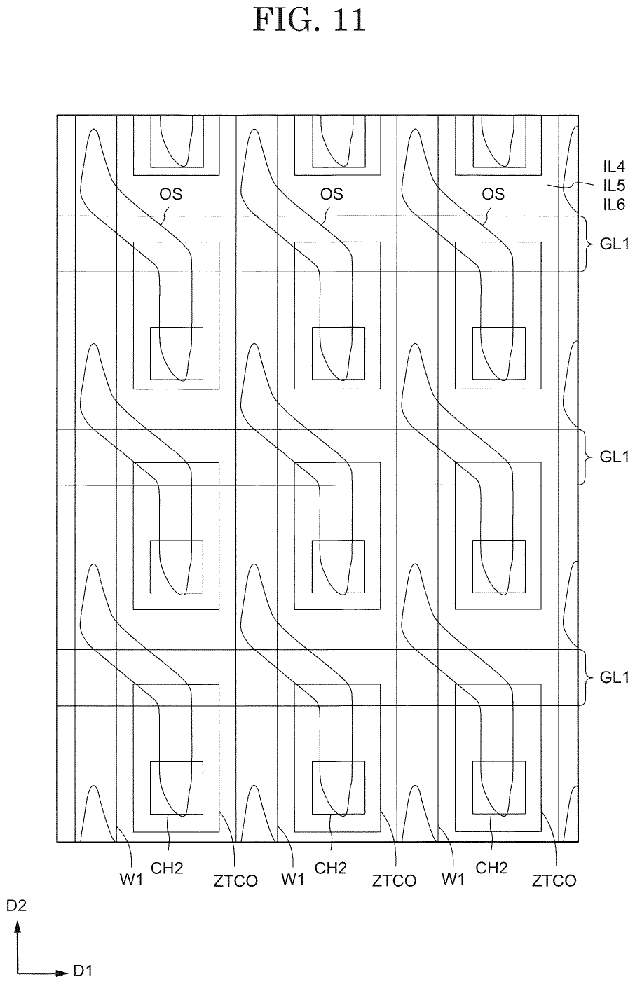

As shown in FIG. 4 and FIG. 11, the contact hole CH2 is provided in the vicinity of the lower end portion of the pattern of the oxide semiconductor layer OS. The contact hole CH2 is formed in the fourth insulating layer IL4, the fifth insulating layer IL5, and the sixth insulating layer IL6. The contact hole CH2 is provided in the region overlapping the pattern of the oxide semiconductor layer OS and not overlapping the gate wiring GL1. The connection electrode ZTCO is formed on the sixth insulating layer IL6. The connection electrode ZTCO overlaps the gate wiring GL1 and the oxide semiconductor layer OS between the two adjacent wirings W1. Therefore, the connection electrode ZTCO is in contact with the oxide semiconductor layer OS in the contact hole CH2 (the contact region ZCON) not overlapping the gate wiring GL1. The oxide semiconductor layer OS is in contact with the wiring W1 opposite the contact hole CH2 with respect to the gate wiring GL1. The contact hole CH2 does not overlap the gate wiring GL2.

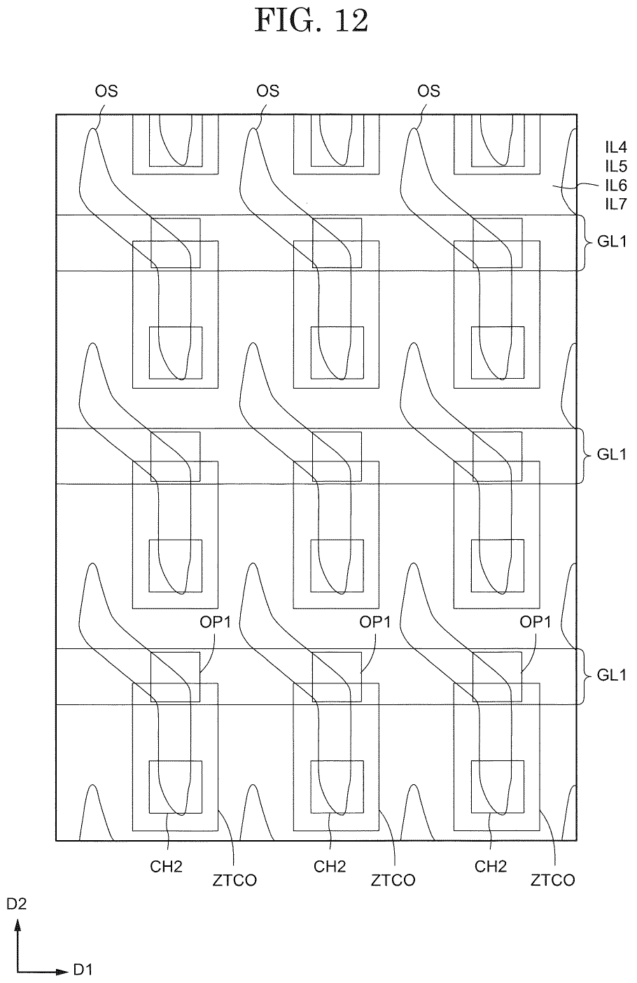

As shown in FIG. 4 and FIG. 12, the opening OP1 is provided in the seventh insulating layer IL7. The opening OP1 is provided in a region overlapping the gate wirings GL1 and GL2. The opening OP1 is provided on the connection electrode ZTCO to expose a part of the connection electrode ZTCO.

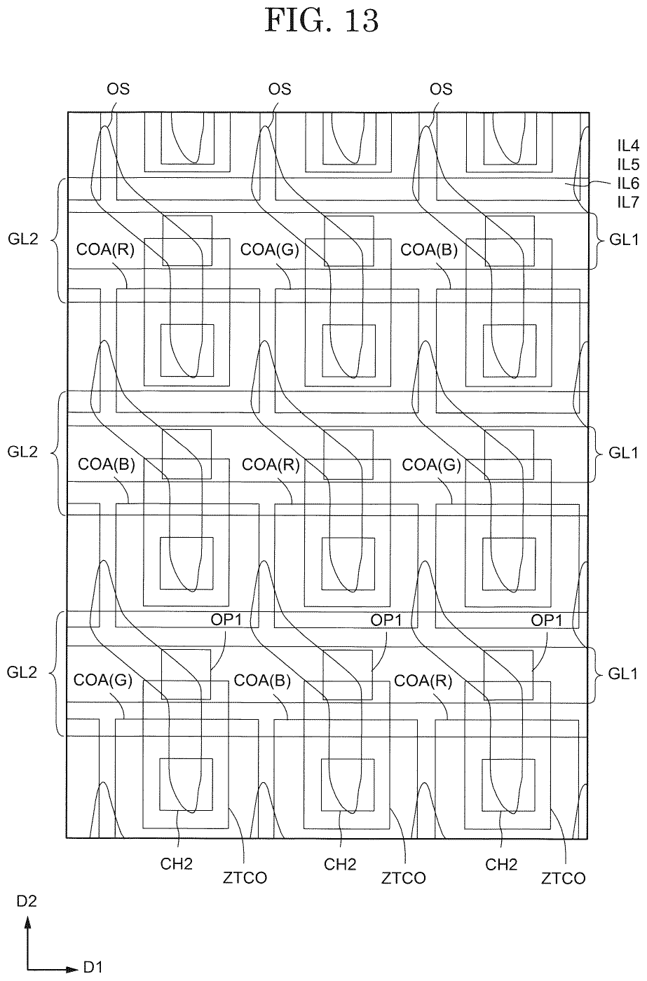

FIG. 13 shows the layout of the color filters. The color filters include a red color filter COA (R), a green color filter COA (G), and a blue color filter COA (B). The color filters are arranged in the order of the color filters COA (R), COA (G), and COA (B) in the first direction D1, and are arranged in the order of the color filters COA (R), COA (B), and COA (G) in the second direction D2. The color filters are arranged so as not to overlap the gate wiring GL. For example, in the first direction D1, the two adjacent color filters COA (R) and COA (G) do not overlap on the wiring W1. In addition, the end portion of the color filter COA (R) in the first direction D1 overlaps the gate wiring GL2. The color filters COA (R), COA (G), and COA (B) are provided to fill the contact hole CH2. Further, the color filters COA (R), COA (G), and COA (B) are provided in a region not overlapping the opening OP1.

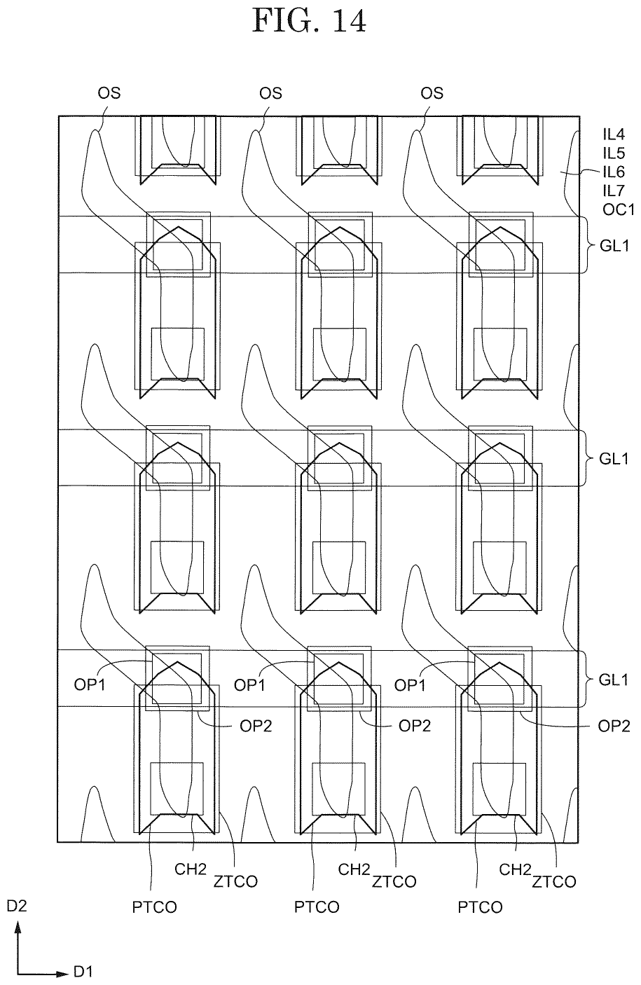

As shown in FIG. 4 and FIG. 14, the opening OP2 is provided in the overcoat OC1. The color filter COA is provided between the seventh insulating layer IL7 and the overcoat OC1, which is not shown in FIG. 14. In the opening region surrounded by the gate wiring GL2 and the wiring W1, the region where the contact hole CH2 is provided also contributes as the opening region. Therefore, as shown in FIG. 4, the color filters COA are provided inside the contact hole CH2. The opening OP2 is also provided in the region overlapping the gate wirings GL1 and GL2. In addition, the opening OP2 is provided so as to surround the opening OP1. Further, the opening OP2 is provided on the connection electrode ZTCO so as to expose a part of the seventh insulating layer IL7 and a part of the connection electrode ZTCO.

As shown in FIG. 4 and FIG. 14, the pixel electrode PTCO is provided on the overcoat OC1 so as to be connected to the connection electrode ZTCO via the openings OP1 and OP2. In particular, the pixel electrode PTCO is connected to the connection electrode ZTCO inside the opening OP1 and inside the opening OP2. As shown in FIG. 4, the pixel electrode PTCO is in contact with the sixth insulating layer IL6 inside the opening OP2. Further, in the sixth insulating layer IL6, the thickness of the region in contact with the pixel electrode PTCO may be smaller than the thickness of the region in contact with the connection electrode ZTCO. Since the pixel electrode PTCO is in contact with the sixth insulating layer IL6 inside the opening OP1, it is possible to suppress moisture derived from the organic layer from entering the oxide semiconductor layer OS via the sixth insulating layer IL6. The pixel electrode PTCO overlaps the gate wiring GL1, the oxide semiconductor layer OS, and the connection electrode ZTCO between the adjacent wirings W1 in the first direction D1.

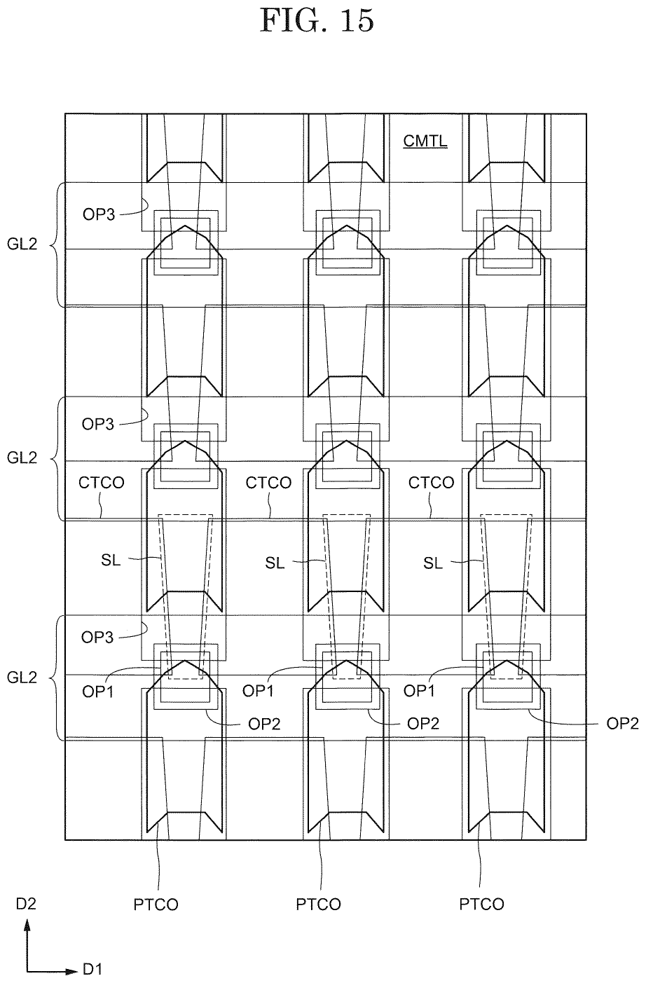

As shown in FIG. 4 and FIG. 15, the common auxiliary electrode CMTL is arranged in a lattice pattern extending in each of the first direction D1 and the second direction D2. In the common auxiliary electrode CMTL, the region extending in the second direction D2 overlaps the wiring W1 (not shown). Further, in the common auxiliary electrode CMTL, the region extending in the first direction D1 overlaps the gate wiring GL1 (not shown), the gate wiring GL2, and the openings OP1 and OP2. The common electrode CTCO is provided in an island shape in the region overlapping the wiring W1. In addition, since a plurality of common electrodes CTCO are provided on and in contact with the common auxiliary electrode CMTL, the same potential is supplied to the plurality of common electrodes CTCO. In the first direction D1, the gap between the two adjacent common electrodes CTCO functions as a slit SL in the FFS mode. The corner portions of the common electrode CTCO are arranged inside the openings OP1 and OP2.

### [9. Materials of Each Member of Display Device 10]

A rigid substrate having light transmittance and no flexibility, such as a glass substrate, a quartz substrate, or a sapphire substrate, can be used as the array substrate SUB1 and the counter substrate SUB2.

A metal material can be used as the gate wirings GL1 and GL2, the wirings W1, W2, and W3, and the common auxiliary electrode CMTL. For example, aluminum (Al), titanium (Ti), chromium (Cr), cobalt (Co), nickel (Ni), molybdenum (Mo), hafnium (Hf), tantalum (Ta), tungsten (W), bismuth (Bi), copper (Cu), or silver (Ag), or an alloy or compound thereof is used as the metal material. The above-described metal materials may be used in a single layer or a stacked layer as a member of the electrode or the like.

Common inorganic insulating materials can be used as the first insulating layer IL1 to the ninth insulating layer IL9. For example, as the first insulating layer IL1 to the ninth insulating layer IL9, an inorganic insulating layer such as silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), or aluminum nitride (AlNₓ) can be used as a single layer or a stacked layer.

SiOₓN_{y} and AlOₓN_{y} are a silicon compound and aluminum compound containing a smaller proportion (x>y) of nitrogen (N) than oxygen (O). SiNₓO_{y} and AlNₓO_{y} are a silicon compound and aluminum compound containing a smaller proportion (x>y) of oxygen than nitrogen.

In the present embodiment, the first insulating layer IL1 includes silicon nitride, thereby suppressing an impurity from the array substrate SUB1 from entering the semiconductor layer S. In addition, silicon nitride and silicon oxide may be stacked as the third insulating layer IL3. Further, silicon oxide may be used as the fourth insulating layer IL4. By using silicon nitride as the seventh insulating layer IL7 and the eighth insulating layer IL8, it is possible to suppress the intrusion of moisture from the organic layer. For the second insulating layer IL2, the fifth insulating layer IL5, the sixth insulating layer IL6, and the ninth insulating layer IL9, the inorganic insulating materials described above may be used as appropriate.

An organic insulating material such as a polyimide resin, an acryl resin, an epoxy resin, a silicone resin, a fluororesin, or a siloxane resin can be used as the overcoats OC1, OC2, and OC3 and the spacer PS.

An oxide semiconductor having semiconductor properties can be used as the oxide semiconductor layer OS. The oxide semiconductor layer OS has light transmittance. For example, an oxide semiconductor containing two or more metals including indium (In) is used as the oxide semiconductor layer OS. For example, an oxide semiconductor containing indium (In), gallium (Ga), zinc (Zn), and oxygen (O) may be used as the oxide semiconductor layer OS. In particular, an oxide semiconductor having a composition ratio of In:Ga:Zn:0=1:1:1:4 may be used. However, the oxide semiconductor layer OS used in the present embodiment is not limited to the above-described composition, and an oxide semiconductor having a composition other than that described above can also be used. For example, the proportion of In may be larger in order to improve the mobility. In addition, the proportion of Ga may be larger in order to increase the bandgap and reduce the effect of photoirradiation. The oxide semiconductor layer OS may be amorphous or polycrystalline. The oxide semiconductor layer OS may be a mixed phase of amorphous and crystalline.

In addition, within the oxide semiconductor layer OS, the oxide semiconductor region OS2 is a region to which an impurity element such as argon (Ar), phosphorus (P), or boron (B) is added. Further, the oxide semiconductor region OS1 is a region to which no impurity element is added.

Low-temperature polysilicon is used as the semiconductor layer S. The semiconductor layer S includes semiconductor regions S1, S2, and S3. A high-concentration impurity element is added to the semiconductor region S2, and a low-concentration impurity element is added to the semiconductor region S3. In addition, the semiconductor region S1 is a region to which no impurity element is added or to which a low-concentration impurity element is added. Phosphorus is added to the semiconductor layer S of the n-type transistor Tr2-1, and boron is added to the semiconductor layer S of the p-type transistor Tr2-2.

A transparent conductive material is used as the connection electrode ZTCO, the pixel electrode PTCO, and the common electrode CTCO. A mixture of indium oxide and tin oxide (ITO) or a mixture of indium oxide and zinc oxide (IZO) can be used as the transparent conductive material. A material other than the above may be used as the transparent conductive layer.

### [10. First Modification]

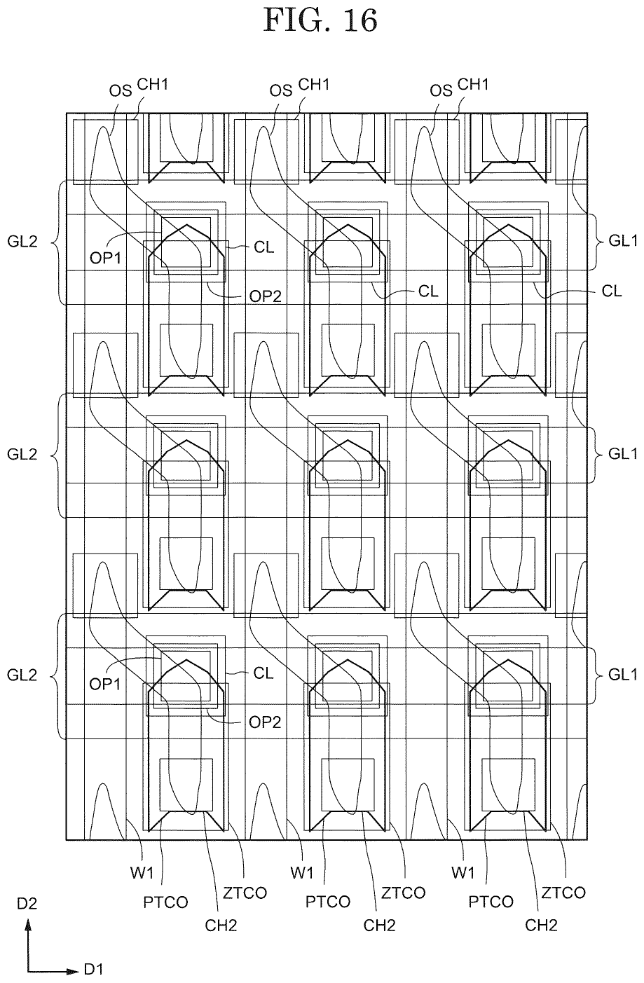

In the present embodiment, a display device having a configuration different from the configuration of the display device 10 shown in the first embodiment will be described with reference to FIG. 16 to FIG. 18. Specifically, the configuration for connecting the pixel electrode PTCO and the connection electrode ZTCO is different. Therefore, the configuration for connecting the pixel electrode PTCO and the connection electrode ZTCO will be described in detail, and other configurations will be omitted as appropriate.

In the end view illustrated in FIG. 8, a part of the end portion of the connection electrode ZTCO provided on the sixth insulating layer IL6 is provided inside the opening OP1 of the seventh insulating layer IL7. That is, when the opening OP1 of the seventh insulating layer IL7 is formed, the sixth insulating layer IL6 exposed from the connection electrode ZTCO is exposed by the etching gas, and the sixth insulating layer IL6 may be removed. Therefore, in the sixth insulating layer IL6, the thickness of the region in contact with the pixel electrode PTCO may be smaller than the thickness of the region in contact with the connection electrode ZTCO. For example, in the case where the color filter COA or the overcoat CO1 is in contact with the region where the sixth insulating layer IL6 is exposed due to the mask misalignment, moisture contained in the color filter COA or the overcoat CO1 may enter the oxide semiconductor layer OS via the sixth insulating layer IL6. In this case, if the thickness of the region in contact with the connection electrode ZTCO in the sixth insulating layer IL6 is sufficiently thick, it is possible to suppress the influence of moisture on the characteristics of the transistor Tr1. However, in the case where the thickness of the region in contact with the connection electrode ZTCO is small in the sixth insulating layer IL6, the moisture may affect the characteristics of the transistor Tr1.

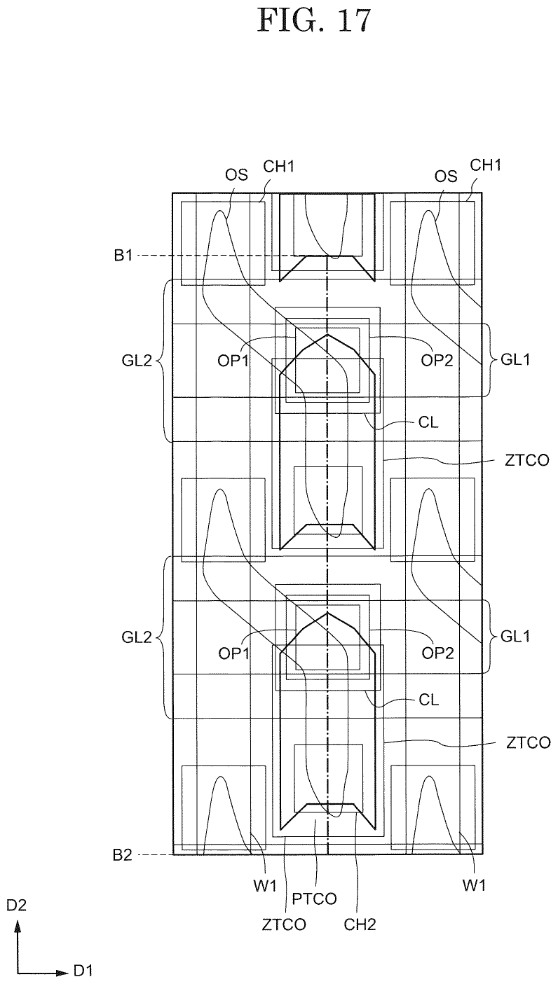

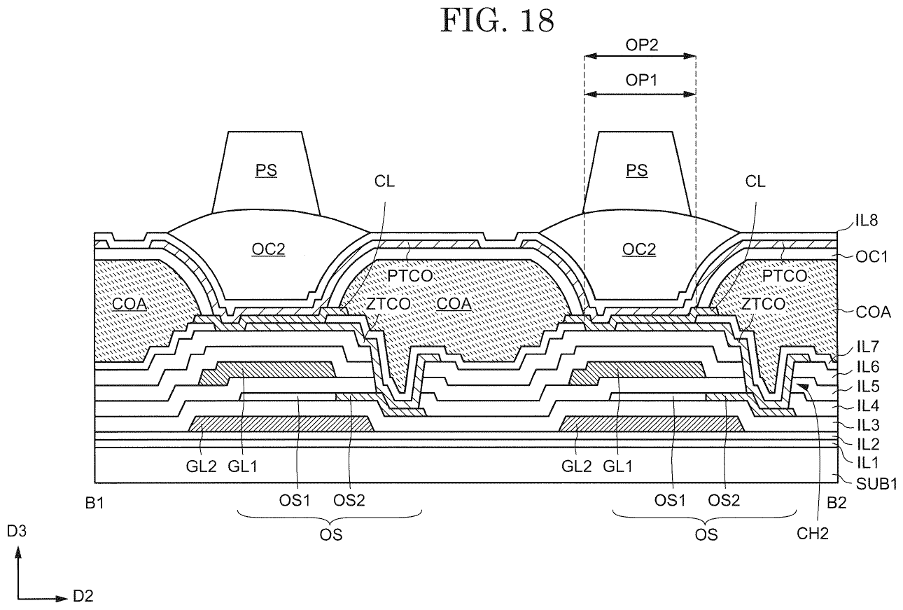

FIG. 16 is a layout diagram of a plurality of pixels arranged in the display region of the display device 10 according to an embodiment of the present invention. FIG. 17 is an enlarged view of a part of a pixel among the plurality of pixels shown in FIG. 16. FIG. 18 is an end view of the pixel shown in FIG. 17 taken along a line B1-B2.

In FIG. 16 to FIG. 18, the structures from the array substrate SUB1 to the seventh insulating layer IL7 are similar to the structures described in FIG. 4 to FIG. 11. In addition, the layouts of the pixel electrode PTCO, the common electrode CTCO, and the common auxiliary electrode CMTL are also similar to those of the first embodiment, and may be referred to as appropriate. In the present modification, in the display device, in order to suppress the sixth insulating layer IL6 from being exposed due to the opening OP1 of the seventh insulating layer IL7, a conductive layer CL is provided so as to cover the opening OP1. As a result, since the sixth insulating layer IL6 is covered with the conductive layer CL, it is possible to prevent an organic layer from coming into contact with the sixth insulating layer IL6 even if a masking misalignment occurs. Therefore, it is possible to prevent water from an organic layer from entering the oxide semiconductor layer OS via the sixth insulating layer IL6. As a result, since the fluctuation in the characteristics of the transistor can be suppressed, the reliability of the display device can be improved.

The conductive layer CL is provided so as to overlap the gate wirings GL1 and GL2. Since the region where the conductive layer CL is provided is a region where light does not transmit, the conductive layer CL does not need to have light transmittance. Therefore, the metal materials described in the gate wirings GL1 and GL2 and the wirings W1 to W2 may be used as the conductive layer CL. Alternatively, the transparent conductive materials described in the connection electrode ZTCO, the pixel electrode PTCO, and the common electrode CTCO may be used as the conductive layer CL.

By providing the conductive layer CL on the connection electrode ZTCO and the seventh insulating layer IL7 to cover the opening OP1, the pixel electrode PTCO is connected to the connection electrode ZTCO via the conductive layer CL. As a result, the pixel electrode PTCO and the connection electrode ZTCO can be connected satisfactorily.

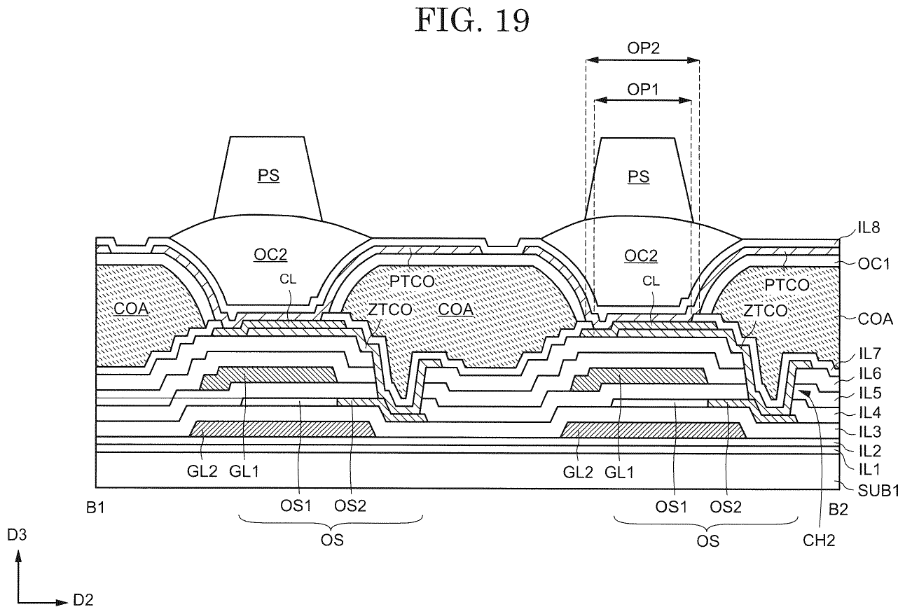

FIG. 19 is another end view of the pixel shown in FIG. 17 taken along a line B1-B2. The difference from the end view shown in FIG. 18 is that the conductive layer CL is provided on the connection electrode ZTCO and the seventh insulating layer IL7 is provided on the conductive layer CL. In addition, the position of the opening OP1 provided in the conductive layer CL and the seventh insulating layer IL7 is similar to that shown in FIG. 16 and FIG. 17. Therefore, the end portion of the opening OP1 is provided on the conductive layer CL. As a result, even if the mask misalignment occurs, it is possible to suppress the organic layer from coming into contact with the sixth insulating layer IL6. Therefore, it is possible to suppress moisture of the organic layer from entering the oxide semiconductor layer OS via the sixth insulating layer IL6. As a result, since the fluctuation in the characteristics of the transistor can be suppressed, the reliability of the display device can be improved.

### [11. Second Modification]

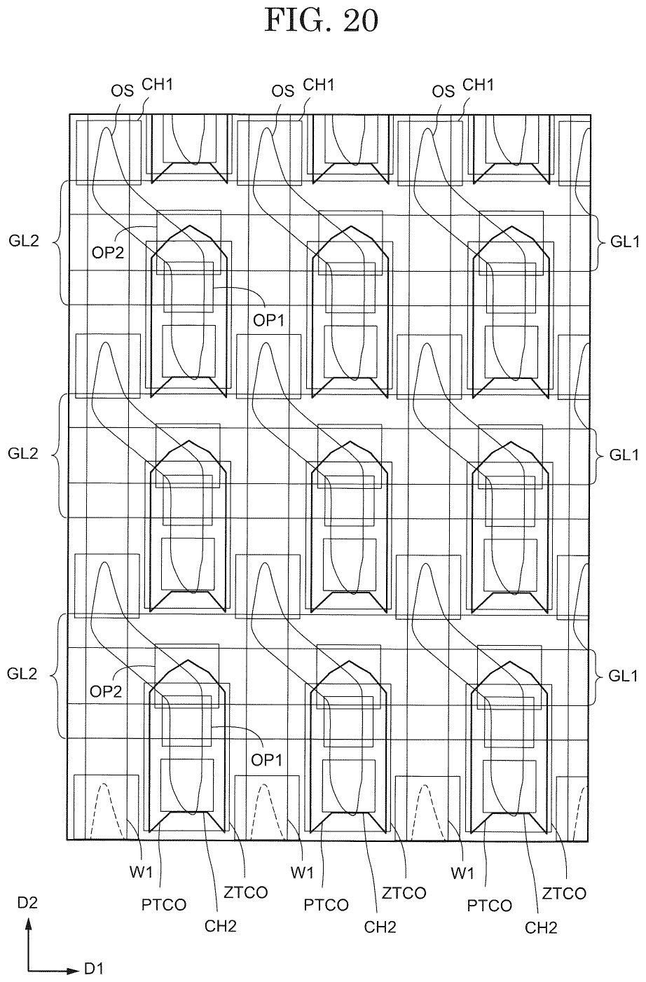

In the present embodiment, a display device having a configuration different from the configuration of the display device 10 shown in the first embodiment will be described with reference to FIG. 20 to FIG. 22. Specifically, the configuration for connecting the pixel electrode PTCO and the connection electrode ZTCO is different. Therefore, the configuration for connecting the pixel electrode PTCO and the connection electrode ZTCO will be described in detail, and other configurations will be omitted as appropriate.

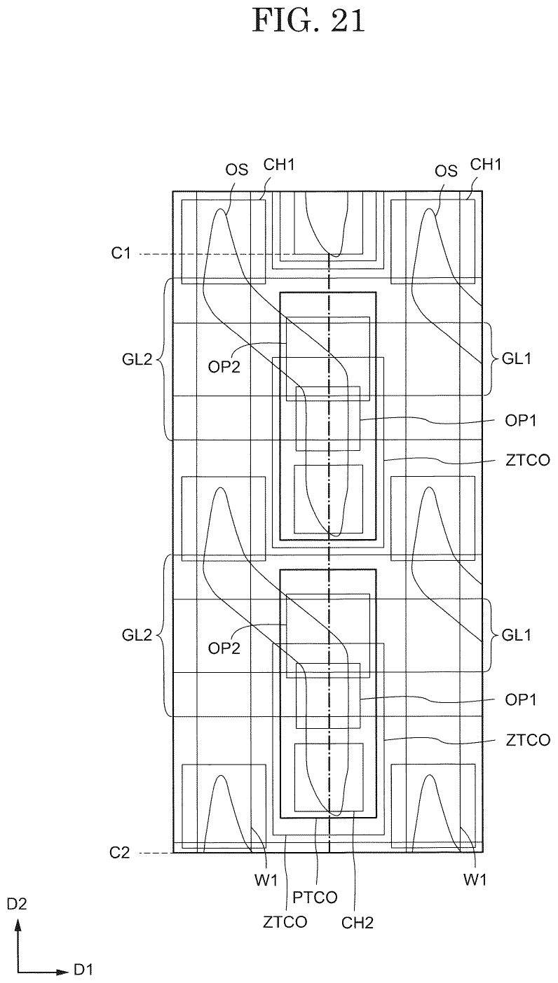

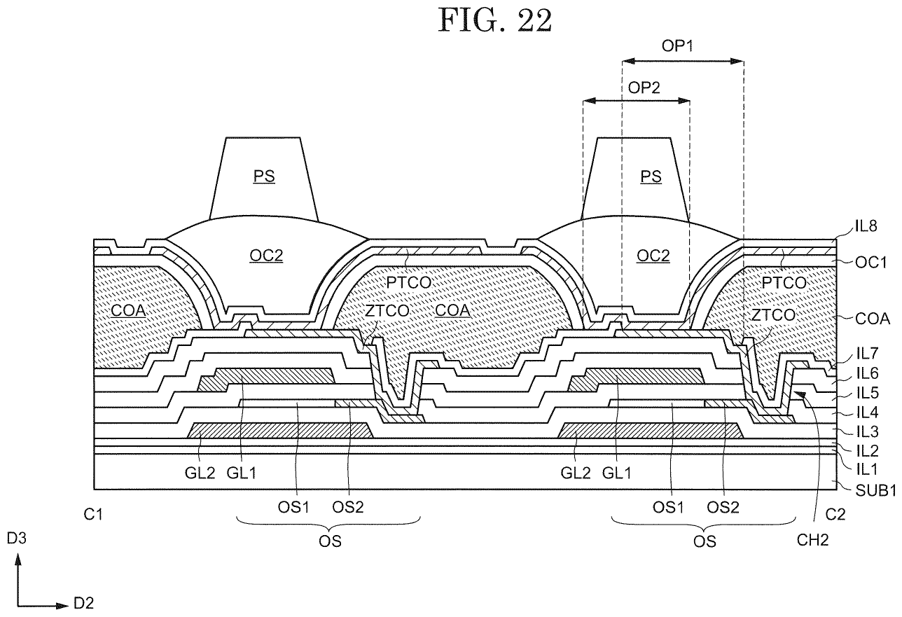

FIG. 20 is a layout diagram of the plurality of pixels arranged in the display region of the display device 10 according to an embodiment of the present invention. FIG. 21 is an enlarged view of a part of a pixel among the plurality of pixels shown in FIG. 20. FIG. 22 is an end view of the pixel shown in FIG. 21 taken along a line C1-C2.

In FIG. 20 to FIG. 22, the structures from the array substrate SUB1 to the seventh insulating layer IL7 are similar to the structures described in FIG. 4 to FIG. 11. In addition, the layouts of the pixel electrode PTCO, the common electrode CTCO, and the common auxiliary electrode CMTL are also similar to those of the first embodiment, and may be referred to as appropriate. In the present modification, in the display device, the position of the opening OP1 is close to the contact hole CH1 in order to suppress the sixth insulating layer IL6 from being exposed due to the opening OP1 of the seventh insulating layer IL7. As a result, the end portion of the opening OP1 is provided on the connection electrode ZTCO, and the end portion of the opening OP2 is provided on the connection electrode ZTCO and the seventh insulating layer IL7. Therefore, it is possible to suppress the organic layer from coming into contact with the sixth insulating layer IL6. Therefore, it is possible to suppress moisture from the organic layer from entering the oxide semiconductor layer OS via the sixth insulating layer IL6. As a result, since the fluctuation in the characteristics of the transistor can be suppressed, the reliability of display device can be improved.

Each of the embodiments described above as an embodiment of the present invention can be appropriately combined and implemented as long as no contradiction is caused. Furthermore, the addition, deletion, or design change of components, or the addition, deletion, or condition change of processes as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A display device comprising:
a plurality of pixels on an insulating surface,
the plurality of pixels comprising:
a transistor with an oxide semiconductor layer, a gate wiring facing the oxide semiconductor layer, and a gate insulating layer between the oxide semiconductor layer and the gate wiring;
a first insulating layer on the transistor;
a first transparent conductive layer on the first insulating layer connected to the oxide semiconductor layer via a first contact hole provided in the first insulating layer and the gate insulating layer;
a second insulating layer having a first opening exposing a part of the first transparent conductive layer;
a first organic layer having a second opening exposing the part of the first transparent conductive layer on the second insulating layer; and
a second transparent conductive layer connected to the first transparent conductive layer on the first organic layer,
wherein
the first contact hole is covered with the first transparent conductive layer, and
a part of an edge of the first transparent conductive layer is arranged inside the second opening.

2. The display device according to claim 1, wherein
the first organic layer is arranged inside the first contact hole.

3. The display device according to claim 1, wherein
the first organic layer includes a color filter.

4. The display device according to claim 1, wherein
the second transparent conductive layer is in contact with the first insulating layer, inside the second opening.

5. The display device according to claim 4, wherein
a thickness of a region in contact with the second transparent conductive layer is smaller than a thickness of a region in contact with the first transparent conductive layer in the first insulating layer.

6. The display device according to claim 1, wherein
the part of the edge of the first transparent conductive layer provided inside the second opening overlaps the gate wiring.

7. The display device according to claim 1, further comprising:
a first conductive layer arranged on the second transparent conductive layer, and
a third transparent conductive layer arranged in contact with the first conductive layer.

8. The display device according to claim 7, wherein
the part of the edge of the first transparent conductive layer provided inside the second opening overlaps the first conductive layer and the third transparent conductive layer in a plan view.

9. The display device according to claim 1, further comprising:
a second organic layer provided inside the second opening; and
a spacer provided on and in contact with the second organic layer,
wherein
the part of the edge of the first transparent conductive layer provided inside the second opening overlaps the spacer in a plan view.

10. The display device according to claim 1, wherein
the part of the edge of the first transparent conductive layer is arranged inside the first opening.

11. The display device according to claim 1, wherein
the first insulating layer includes a first inorganic insulating layer and a second inorganic insulating layer provided on the first inorganic insulating layer.

12. The display device according to claim 11, further comprising:
a second conductive layer connected to the oxide semiconductor layer via a second contact hole provided in the first inorganic insulating layer and the gate insulating layer on the first inorganic insulating layer.

13. The display device according to claim 1, further comprising:
a second conductive layer provided to cover the second opening on top of the first transparent conductive layer and the second insulating layer,
wherein
the second transparent conductive layer is connected to the first transparent conductive layer via the second conductive layer.

14. The display device according to claim 1, wherein
the second transparent conductive layer covers the part of an edge of the first opening and is in contact with the first transparent conductive layer.

15. The display device according to claim 1, wherein
an edge of the first opening is provided on the first transparent conductive layer, and
an edge of the second opening is provided on the first transparent conductive layer and the second insulating layer.

16. The display device according to claim 1, wherein
a plurality of pixels includes a first pixel and a second pixel adjacent to the first pixel in a first direction, and
a distance between the first transparent conductive layer of the first pixel and the first transparent conductive layer of the second pixel is the same as the length of the first contact hole of the first pixel in the first direction.
